(19) United States
(12) Patent Application Publication
(10) Pub. No.: US 2025/0081541 A1
(43) Pub. Date: Mar. 6, 2025

(54) WRAP AROUND BACKSIDE CONTACT FOR S/D WITH BACKSIDE TRENCH EPI AND BSPDN

(71) Applicant: INTERNATIONAL BUSINESS MACHINES CORPORATION, ARMONK, NY (US)

(72) Inventors: Tsung-Sheng Kang, Ballston Lake, NY (US); Tao Li, Slingerlands, NY (US); Ruilong Xie, Niskayuna, NY (US); Nicolas Jean Loubet, GUILDERLAND, NY (US)

(21) Appl. No.: 18/457,793

(22) Filed: Aug. 29, 2023

(51) Int. Cl. H01L 29/786; H01L 23/528; H01L 29/06; H01L 29/423; H01L 29/66

(52) U.S. Cl. CPC H10D 30/6757; H01L 23/5286; H10D 30/014; H10D 30/6735; H10D 30/6748; H10D 62/121

(57) ABSTRACT

A microelectronic structure that includes a nanosheet transistor that includes a first source/drain and a second source/drain. A trench epi extending from a backside surface of the first source/drain. A backside contact that wraps around the trench epi and is in contact with a backside surface of the first source/drain.

### BACKGROUND

The present invention generally relates to the field of microelectronics, and more particularly to formation of backside source/drain trench epi and formation a wrap around backside contact.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form separate backside contacts that have enough surface contact with the source/drains.

### BRIEF SUMMARY

Additional aspects and/or advantages will be set forth in part in the description which follows and, in part, will be apparent from the description, or may be learned by practice of the invention.

A microelectronic structure that includes a nanosheet transistor that includes a first source/drain and a second source/drain. A trench epi extending from a backside surface of the first source/drain. A backside contact that wraps around the trench epi and is in contact with a backside surface of the first source/drain.

A microelectronic structure that includes a nanosheet transistor that includes a first source/drain and a second source/drain. A bottom dielectric isolation layer located on a backside surface of the first source/drain. A trench epi extending from a backside surface of the first source/drain and the trench epi extends through the bottom dielectric layer. A backside contact that wraps around the trench epi and is in contact with a backside surface of the first source/drain.

A method that includes the steps of forming a nanosheet transistor that includes a first source/drain and a second source/drain. Flipping the nanosheet transistor over for backside processing. Forming a first backside interlayer dielectric layer and forming a second backside interlayer dielectric layer. Forming a trench to expose the backside surface of the first source/drain. Forming a sacrificial liner on the sidewalls of the trench. Growing a trench epi from the backside surface of the first source/drain and the sacrificial liner acts a retaining wall for the trench epi growth. Removing the sacrificial liner and forming a backside contact that wraps around the trench epi and is in contact with the backside surface of the first source/drain.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of multiple nano devices/nanosheet transistors, in accordance with the embodiment of the present invention.

FIG. 2 illustrates a cross section X of the nano device/nanosheet transistor after the completion of the frontside processing of the nanosheet transistors, in accordance with the embodiment of the present invention.

FIG. 3 illustrates a cross section Y1 of the gate region after the completion of the frontside processing of the nanosheet transistors, in accordance with the embodiment of the present invention.

FIG. 4 illustrates a cross section Y2 of the source/drain region after the completion of the frontside processing of the nanosheet transistors, in accordance with the embodiment of the present invention.

FIG. 5 illustrates a cross section X of the nano device/nanosheet transistor after the flipping of the device over for backside processing, removal of the first substrate, the etch stop, and the second substrate, and the formation of a first backside interlayer dielectric layer and a second backside interlayer dielectric layer, in accordance with the embodiment of the present invention.

FIG. 6 illustrates a cross section Y1 of the gate region after the flipping of the device over for backside processing, removal of the first substrate, the etch stop, and the second substrate, and the formation of a first backside interlayer dielectric layer and a second backside interlayer dielectric layer, in accordance with the embodiment of the present invention.

FIG. 7 illustrates a cross section Y2 of the source/drain region after the flipping of the device over for backside processing, removal of the first substrate, the etch stop, and the second substrate, and the formation of a first backside interlayer dielectric layer and a second backside interlayer dielectric layer, in accordance with the embodiment of the present invention.

FIG. 8 illustrates a cross section X of the nano device/nanosheet transistor after the formation of a first lithography layer and the formation of a backside contact trench, in accordance with the embodiment of the present invention.

FIG. 9 illustrates a cross section Y1 of the gate region after the formation of a first lithography layer and the formation of a backside contact trench, in accordance with the embodiment of the present invention.

FIG. 10 illustrates a cross section Y2 of the source/drain region after the formation of a first lithography layer and the formation of a backside contact trench, in accordance with the embodiment of the present invention.

FIG. 11 illustrates a cross section X of the nano device/nanosheet transistor after removal of the placeholder and gouging of the source/drain, in accordance with the embodiment of the present invention.

FIG. 12 illustrates a cross section Y1 of the gate region after removal of the placeholder and gouging of the source/drain, in accordance with the embodiment of the present invention.

FIG. 13 illustrates a cross section Y2 of the source/drain region after removal of the placeholder and gouging of the source/drain, in accordance with the embodiment of the present invention.

FIG. 14 illustrates a cross section X of the nano device/nanosheet transistor after formation of a sacrificial trench liner, in accordance with the embodiment of the present invention.

FIG. 15 illustrates a cross section Y1 of the gate region after formation of a sacrificial trench liner, in accordance with the embodiment of the present invention.

FIG. 16 illustrates a cross section Y2 of the source/drain region after formation of a sacrificial trench liner, in accordance with the embodiment of the present invention.

FIG. 17 illustrates a cross section X of the nano device/nanosheet transistor after formation of a backside trench epi, in accordance with the embodiment of the present invention.

FIG. 18 illustrates a cross section Y1 of the gate region after formation of a backside trench epi, in accordance with the embodiment of the present invention.

FIG. 19 illustrates a cross section Y2 of the source/drain region after formation of a backside trench epi, in accordance with the embodiment of the present invention.

FIG. 20 illustrates a cross section X of the nano device/nanosheet transistor after removal of the sacrificial trench liner and the formation of the wrap around backside contact, in accordance with the embodiment of the present invention.

FIG. 21 illustrates a cross section Y1 of the gate region after removal of the sacrificial trench liner and the formation of the wrap around backside contact, in accordance with the embodiment of the present invention.

FIG. 22 illustrates a cross section Y2 of the source/drain region after removal of the sacrificial trench liner and the formation of the wrap around backside contact, in accordance with the embodiment of the present invention.

FIG. 23 illustrates a cross section X of the nano device/nanosheet transistor after formation of a backside-power-distribution-network (BSPDN), in accordance with the embodiment of the present invention.

FIG. 24 illustrates a cross section Y1 of the gate region after formation of a backside-power-distribution-network (BSPDN), in accordance with the embodiment of the present invention.

FIG. 25 illustrates a cross section Y2 of the source/drain region after formation of a backside-power-distribution-network (BSPDN), in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming a wrap around backside contact. The backside of the source/drain is gouged to create a crater/valley. Gouging of the source/drain is an optional processing step. A sacrificial liner is formed along the sides of the backside interlayer dielectric layer towards the backside of the source/drain. The sacrificial liner forms a valley/trench within the backside interlayer dielectric layer and the source/drain. The gouged surface of the source/drain forms the bottom boundary/wall of the valley/trench. A trench epi or source/drain trench epi is grown from the backside surface of the source/drain. The trench epi or source/drain trench epi extends vertically up into the valley/trench, where the sacrificial liner acts as retaining walls during the growth of the trench epi or source/drain trench epi. The sacrificial liner is removed, thus creating empty space around the sidewalls of the trench epi. A backside contact is formed around the trench epi, such that the backside contact is in direct contact with the sides of the trench epi, a top surface of the trench epi, and is in contact with a portion of the gouged surface of the source/drain. By forming the trench epi, the overall amount of surface area of the source/drain available for forming an interface/contact with the backside contact is increased. Furthermore, the trench epi allows for the formation of a wrap around backside contact.

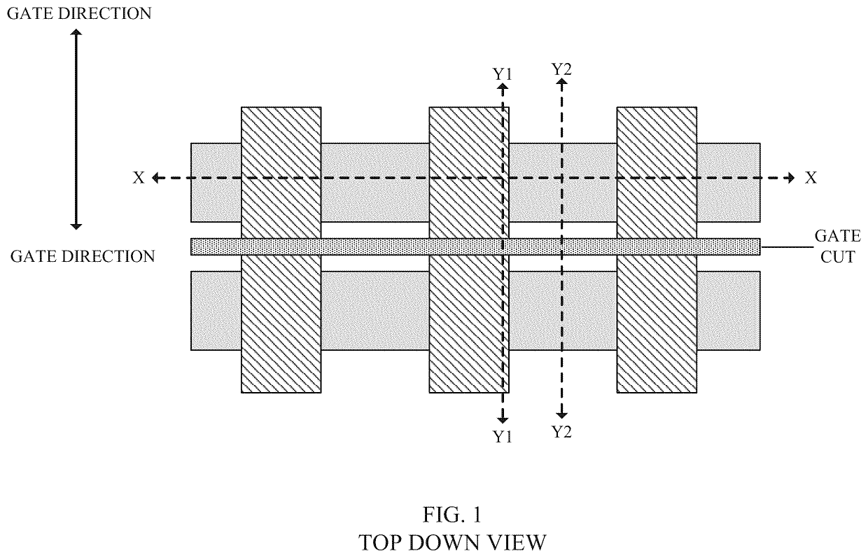

FIG. 1 illustrates a top-down view of multiple devices, in accordance with the embodiment of the present invention. The cross-section X extends horizontally through the nano stacks (nanosheet transistors) of one of the devices. Cross section Y1 is perpendicular to cross section X, where cross section Y1 is through a gate region that spans across multiple nano stacks. Cross section Y2 is perpendicular to cross section X, where cross section Y2 is through a source/drain region that spans across multiple nano stacks. Cross-section X is perpendicular to the gate direction and cross-sections Y1 and Y2 are parallel to the gate direction.

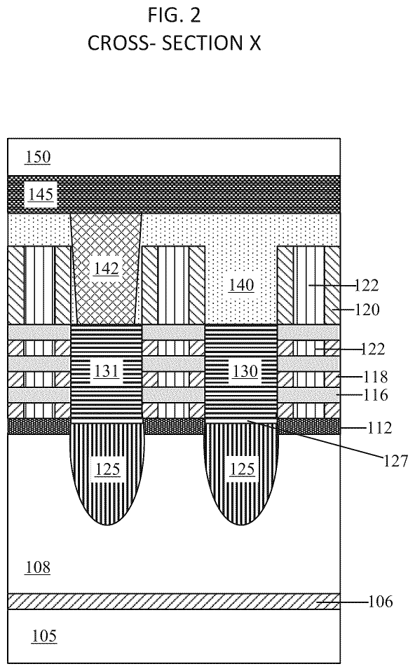

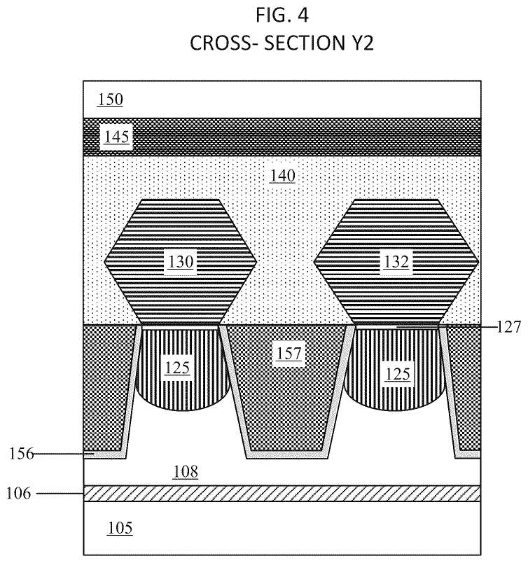

Referring now to FIGS. 2, 3, and 4, a structure is shown during an intermediate step of a method of fabricating stacked nano devices, such as, a stacked nanosheet transistor structure after the completion of the frontside processing of the nanosheet transistors.

FIGS. 2, 3, and 4 illustrate the processing stage after the completion of the frontside processing of the nanosheet transistors.

FIG. 2 illustrates the nanosheet transistors that includes a first substrate 105, an etch stop 106, a second substrate 108, a bottom dielectric isolation layer 112, a plurality of nanosheet columns. Each of the nanosheet columns includes of a plurality of channel layers 116, an inner spacer 118, an upper spacer 120, and a gate 122. The plurality of channel layers 116 can be comprised of, for example, Si. The source/drains 130, 131, 132 are located between nanosheet columns. Placeholder 125 can be located beneath source/drains 130, 131, 132 and a sacrificial barrier layer 127 is located between the placeholders 125 and the source/drains 130, 131, 132. A frontside interlayer dielectric layer 140 can be located on top of the source/drains 130, 131, 132 and on top of the gate 122.

The first substrate 105 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein. Gate 122 can be comprised of, for example, a gate dielectric liner, such as high-k dielectric like HfO₂, ZrO₂, HfLₐOx, etc., and work function layers, such as TiN, TiAlC, TiC, etc., and conductive metal fills, like W.

The source/drains 130, 131, and 132, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

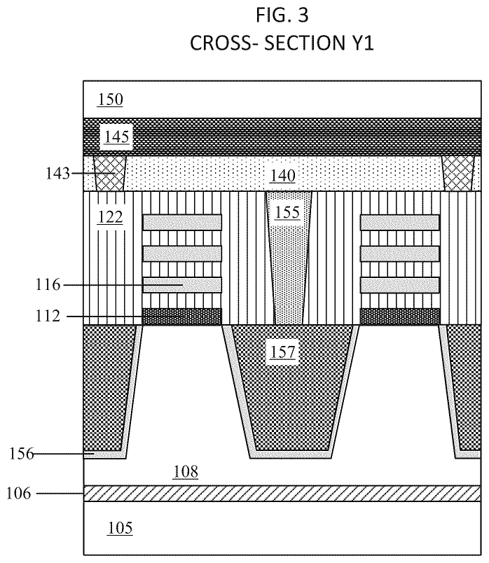

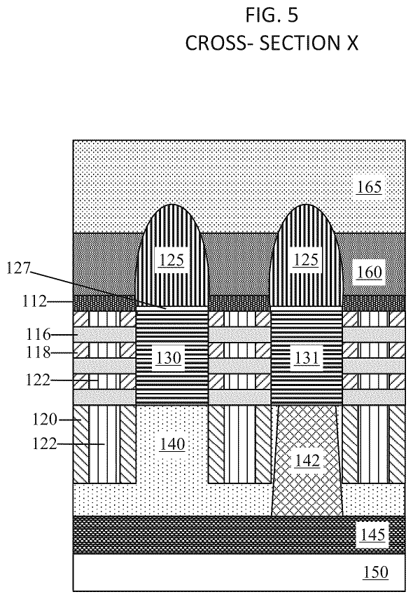

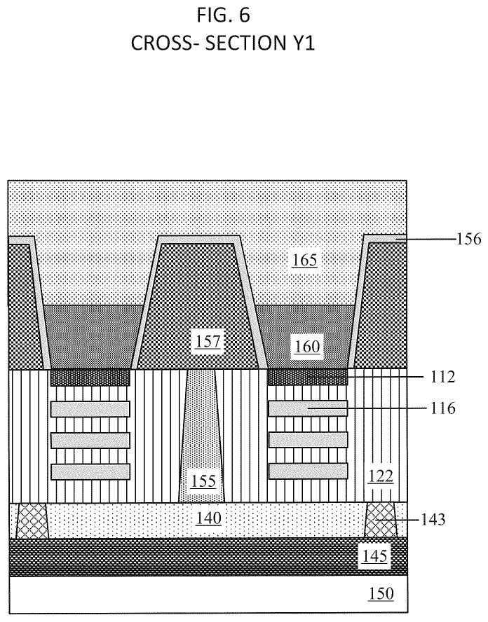

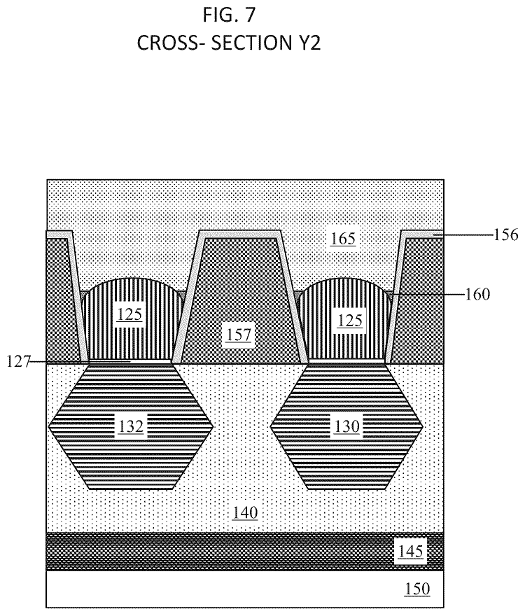

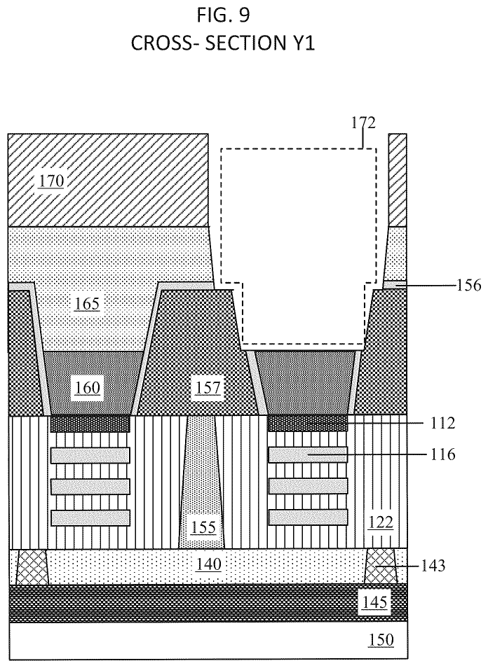

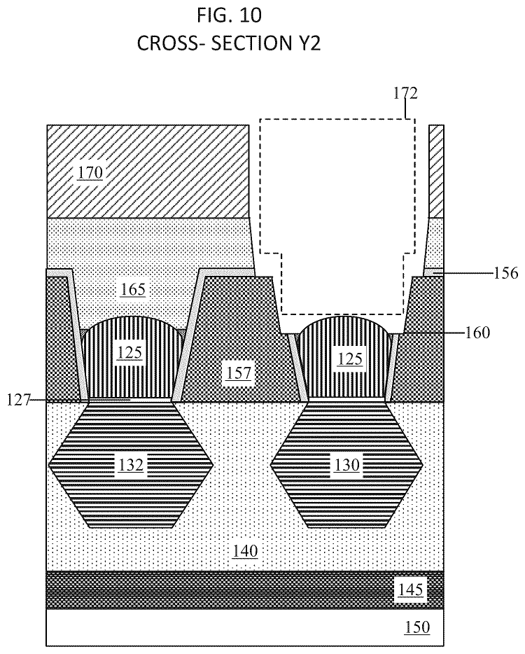

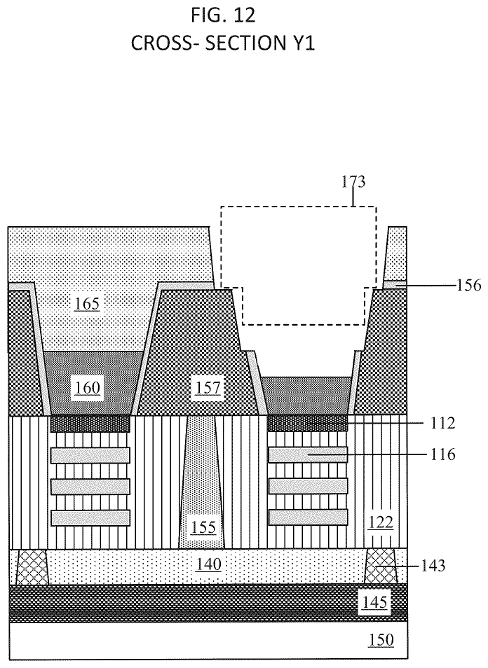

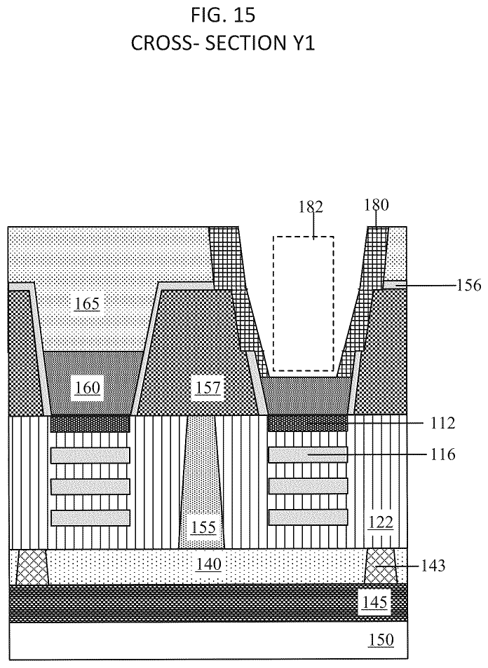

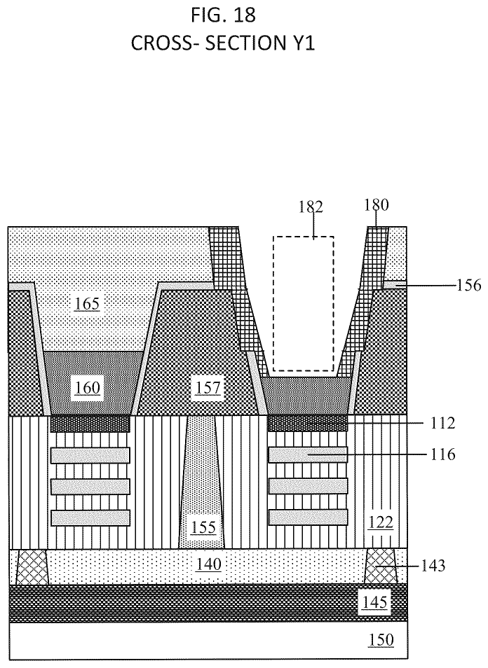

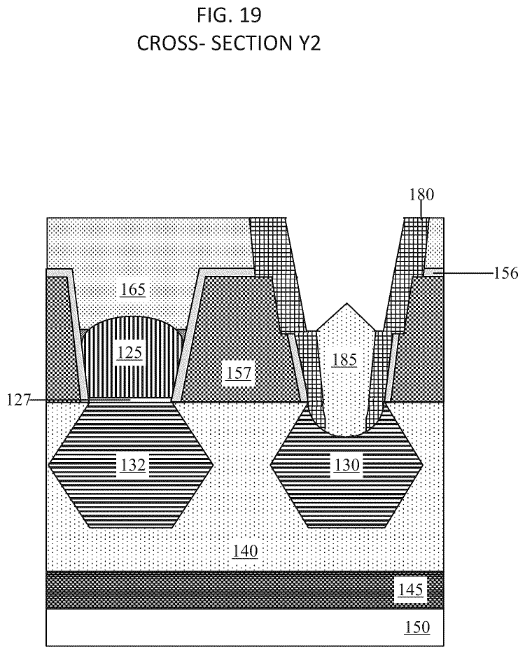

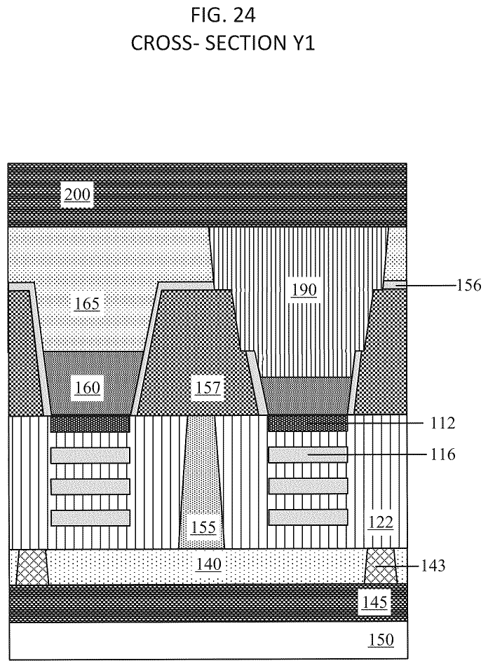

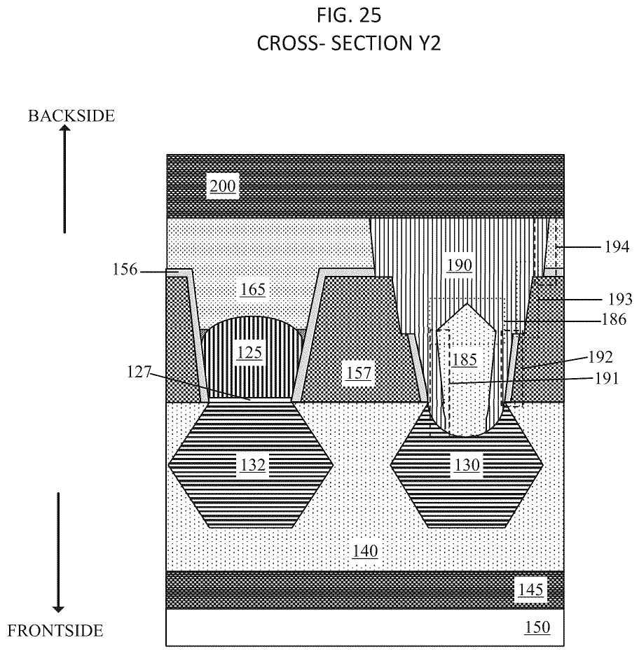

The formation of the source/drain regions creates trenches in (not shown) the second substrate 108. These trenches are field with a liner 156 and a shallow trench isolation layer 157. Gate 122 of different devices are separate by a gate cut 155, as illustrated in FIG. 3. Frontside source/drain contact 142 can be formed in the frontside interlayer dielectric layer 140, where the frontside source/drain contact 142 is in contact with the frontside of the source/drain 131. Frontside gate contacts 143, as illustrated in FIG. 3, are formed in the frontside interlayer dielectric layer 140. A back-end-of-the-line (BEOL) layer 145 is formed on top of the frontside interlayer dielectric layer 140, on top of the frontside source/drain contacts 142, and on top of the frontside gate contacts 143. A carrier wafer 150 is formed on top of the BEOL layer 145. The carrier wafer 150 allows for the nano device/nanosheet transistors to be flipped over for backside processing. FIGS. 5-25 illustrate the backside processing stages of the nano device/nanosheet transistors.

FIGS. 5, 6, and 7 illustrate the processing stage after the flipping of the device over for backside processing, removal of the first substrate 105, the etch stop 106, and the second substrate 105, and the formation of a first backside interlayer dielectric layer 160 and a second backside interlayer dielectric layer 165. The nano devices/nanosheet transistors are flipped over for backside processing. The first substrate 105 is removed, then the etch stop 106 and the second substrate 108 is removed to expose the backside surface of the underlying nanosheet transistors. A first backside interlayer dielectric layer 160 is formed on the backside surface of the bottom dielectric isolation layer 112 and around the placeholder 125. The first backside interlayer dielectric layer 160 does not completely enclose/encapsulate the placeholder 125. Placeholder 125 extends past the top surface of the first backside interlayer dielectric layer 160. The first backside interlayer dielectric layer 160 can be comprised of, for example, SiOC. A second backside interlayer dielectric layer 165 is formed on top of the first backside interlayer dielectric layer 160, on top of the placeholder 125, and on top of liner 156. The second backside interlayer dielectric layer 165 can be comprised of, for example, SiN. The first backside interlayer dielectric layer 160 and the second backside interlayer dielectric layer 165 are comprised of different dielectric materials.

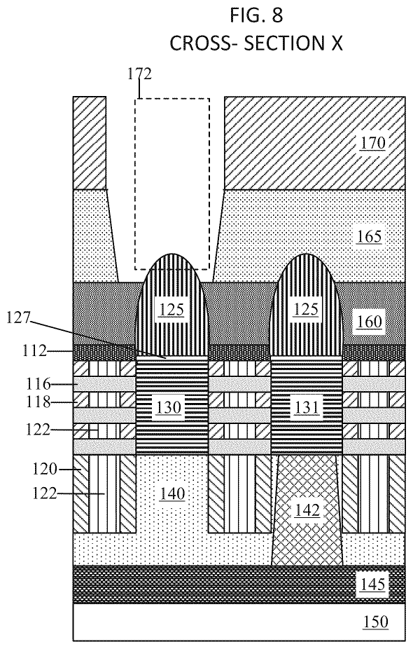

FIGS. 8, 9, and 10 illustrate the processing stage after the formation of a first lithography layer 170 and the formation of a backside contact trench 172. The first lithography layer 170 is formed on top of the second backside interlayer dielectric layer 165. The first lithography layer 170 is patterned and a backside contact trench 172 is formed. Portions of the second backside interlayer dielectric layer 165, portions of liner 156, and portions of the shallow trench isolation layer 157 are removed during the formation of the backside contact trench 172. The backside contact trench 172 exposes a backside surface of one of the placeholders 125.

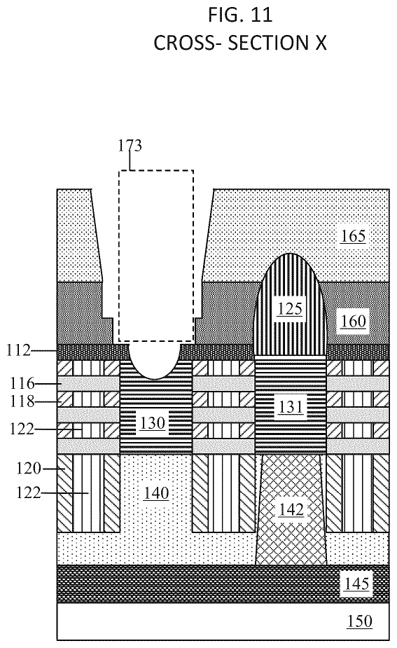

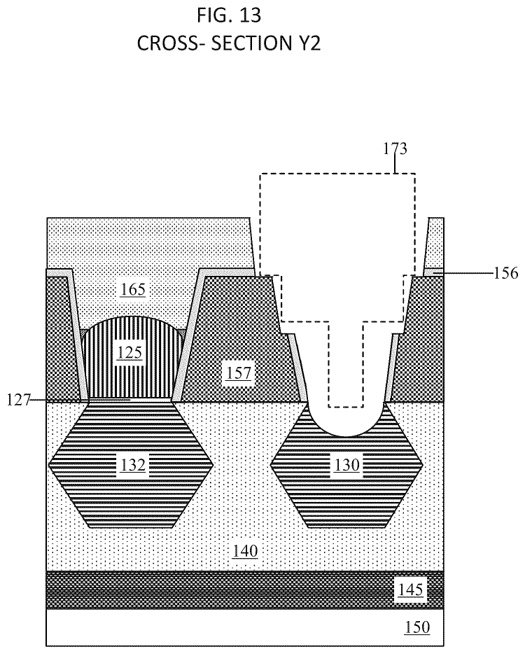

FIGS. 11, 12, and 13 illustrate the processing stage after removal of the placeholder 125 and gouging of the source/drain 130. The first lithography layer 170 is removed and then the placeholder 125 is removed to expose the backside surface of the source/drain 130. The first backside interlayer dielectric layer 160 is laterally etched to widen/increase the width of the backside contact trench 172, (herein refer to as the widen backside contact trench 173). FIGS. 11 and 13 illustrate that the source/drain 130 is gouge, i.e., a removal of a portion of the source/drain 130 to create a crater/valley in the source/drain 130. The gouging procedure is optional, and it does not need to be performed. The gouging process increases the amount of exposed surface area of the source/drain 130.

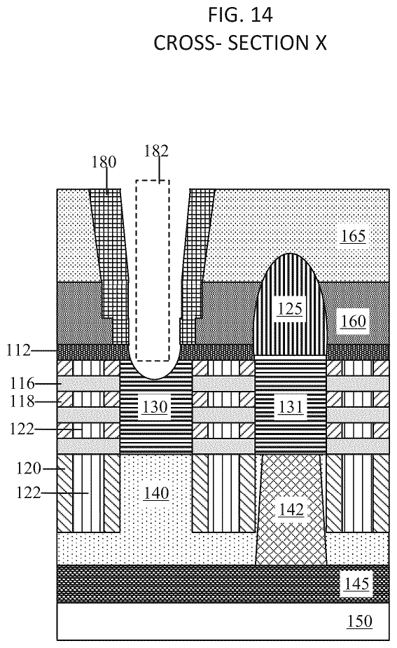

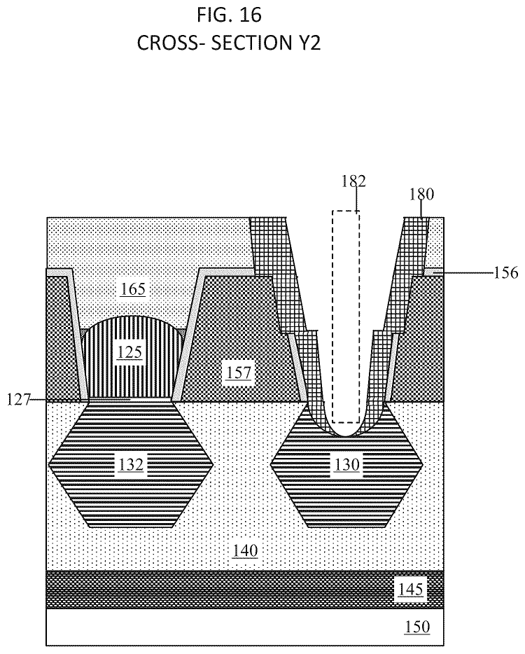

FIGS. 14, 15, and 16 illustrate the processing stage after formation of a sacrificial trench liner 180. Sacrificial trench liner 180 is formed along the sidewalls of widen backside contact trench 173. As illustrated in FIG. 14, the sacrificial trench liner 180 extends from the backside surface of the bottom dielectric isolation layer 112 to the top of the second backside interlayer dielectric layer 165. The sacrificial trench liner 180 narrows the width of the widen backside contact trench 173 to form the growth epi trench 182. As illustrated in FIG. 16, the sacrificial trench liner 180 can extend down to the gouged surface of the source/drain 130. The sacrificial trench liner 180 does not completely cover the backside surface of the gouged source/drain 130.

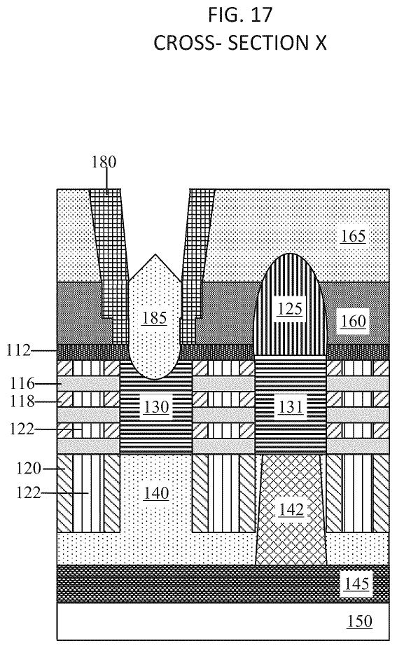

FIGS. 17, 18, and 19 illustrate the processing stage after formation of a backside trench epi 185. A backside trench epi 185 is grown in the growth epi trench 182. The backside trench epi 185 is in contact with a backside surface of the source/drain 130. The sides of the backside trench epi 185 are in contact with bottom dielectric isolation layer 112 and in contact with the sacrificial trench liner 180. The sacrificial trench liner 180 acts as a retaining wall for the growth of the backside trench epi 185.

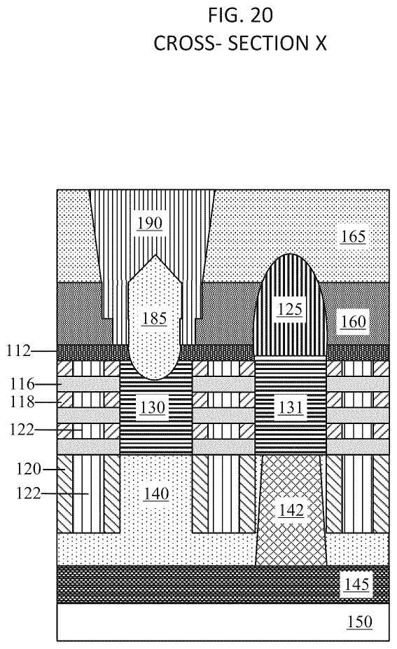

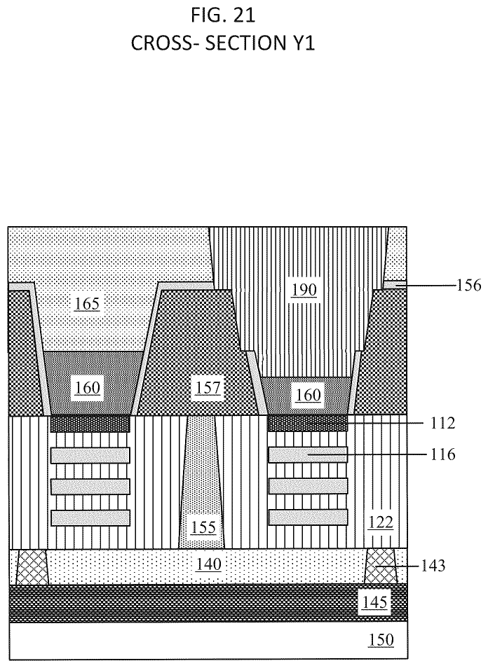

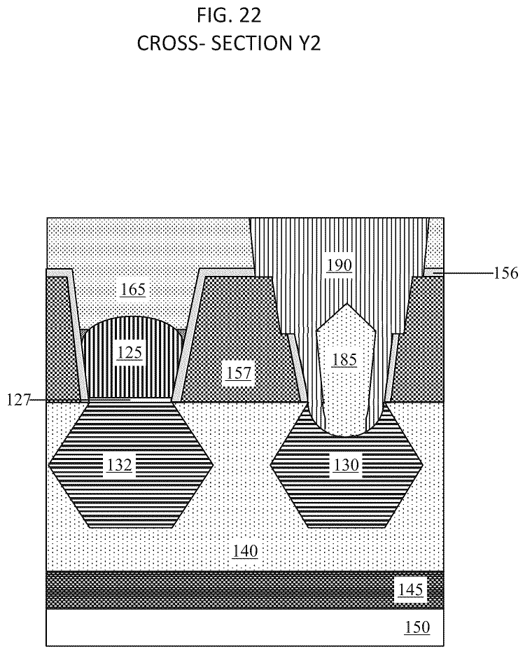

FIGS. 20, 21, and 22 illustrate the processing stage after removal of the sacrificial trench liner 180 and the formation of the wrap around backside contact 190. Sacrificial trench liner 180 is removed, thus exposing the sidewalls of the backside trench epi 185. A wrap around backside contact 190 is formed around the backside trench epi 185. As illustrated in FIG. 20, the wrap around backside contact 190 is in contact with sides and the backside surface of the backside trench epi 185. Furthermore, the wrap around backside contact 190 is in contact with a backside surface of the bottom dielectric isolation layer 112. FIG. 21 illustrates that the wrap around backside contact 190 is in direct contact with the first backside interlayer dielectric layer 160, liner 156, shallow trench isolation layer 157, and the second backside interlayer dielectric layer 165. FIG. 22 illustrates that the wrap around backside contact 190 is also in direct contact with the gouged backside surface of the source/drain 130. The backside trench epi 185 increases the surface area interaction/contact with the wrap around backside contact 190 because the backside trench epi 185 increase the area of interaction with the wrap around backside contact 190.

In the typical situation, a backside contact is only in contact with a backside surface of the source/drain. The typical situation there is a limited amount of available surface area to create a connection between a backside contact and the backside surface of the source/drain.

In contrast the present invention utilizes the backside trench epi 185 acts as an extension of the source/drain 130, thus the backside trench epi 185 increases the amount of available surface area to form the connection between the wrap around backside contact 190 and the combine source/drain 130 and backside trench epi 185. The increase surface area forms a better connection between components when compared to the typical situation.

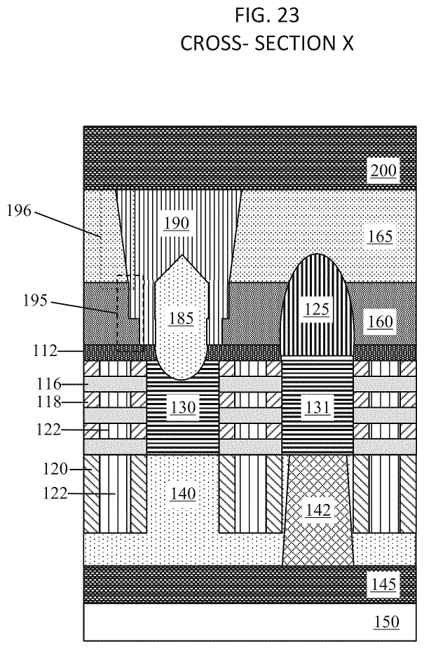

FIGS. 23, 24, and 25 illustrate the processing stage after formation of a backside-power-distribution-network (BSPDN) 200. A backside-power-distribution-network (BSPDN) 200 is formed on top of the second backside interlayer dielectric layer 165 and on top of the wrap around backside contact 190.

FIGS. 23, 24, and 25 illustrate a microelectronic structure that includes a nanosheet transistor that includes a first source/drain 130 and a second source/drain 131. A trench epi 185 extending from a backside surface of the first source/drain 130. A backside contact 190 that wraps around the trench epi 185 and is in contact with a backside surface of the first source/drain 130. The backside surface of the first source/drain 130 is curved from a gouging process (i.e., the valley/crater formed from the gouging). Trench epi 185 includes a tip, as emphasized by dashed box 186, pointing towards the backside of the nanosheet transistor. The backside contact 190 is in contact with the sidewalls of the trench epi 185, as emphasized by dashed box 191, and the backside contact 190 is contact with the tip of the trench epi 185, as emphasized by dashed box 186. The backside contact 190 is in contact with the curved backside surface of the first source/drain 130. A first portion of a sidewall (as emphasized by dashed box 192) of the backside contact 190 is in contact with a liner 156. A second portion of the sidewall (as emphasized by dashed box 193) of the backside contact 190 is in contact with a shallow trench isolation layer 157. A third portion of the sidewall (as emphasized by dashed box 194) of the backside contact 190 is in contact with a backside interlayer dielectric layer (i.e., the second backside interlayer dielectric layer 165).

FIGS. 23, 24, and 25 illustrate a microelectronic structure that includes a nanosheet transistor that includes a first source/drain 130 and a second source/drain 131. A bottom dielectric isolation layer 112 located on a backside surface of the first source/drain 130. A trench epi 185 extending from a backside surface of the first source/drain 130 and the trench epi 185 extends through the bottom dielectric layer 112. A backside contact 190 that wraps around the trench epi 185 and is in contact with a backside surface of the first source/drain 130. The backside contact 190 is in contact with a plurality of sidewalls of the trench epi 185, as emphasized by dashed box 191, and the backside contact 190 is contact with the tip of the trench epi 185, as emphasized by dashed box 186. The backside contact 190 is in contact with the curved backside surface of the first source/drain 130. A first portion of a first sidewall (as emphasized by dashed box 192) of the backside contact 190 is in contact with a liner 156. A second portion of the first sidewall (as emphasized by dashed box 193) of the backside contact 190 is in contact with a shallow trench isolation layer 157. A third portion of the first sidewall (as emphasized by dashed box 194) of the backside contact 190 is in contact with a first backside interlayer dielectric layer (i.e., the second backside interlayer dielectric layer 165). A first portion of a second sidewall (as emphasized by dashed box 195) of the backside contact 190 is in contact with a second backside interlayer dielectric layer (i.e., the first backside interlayer dielectric layer 160), and a second portion of the second sidewall (as emphasized by dash box 196) of the backside contact 190 is in contact with the first backside interlayer dielectric layer (i.e., the second backside interlayer dielectric layer 165). The first backside dielectric layer (i.e., the second backside interlayer dielectric layer 165) and the second backside dielectric layer (i.e., the first backside interlayer dielectric layer 160) are comprised of different dielectric materials.

FIGS. 1-25 illustrate a method that includes the steps of forming a nanosheet transistor that includes a first source/drain 130 and a second source/drain 131. Flipping the nanosheet transistor over for backside processing. Forming a first backside interlayer dielectric layer 160 and forming a second backside interlayer dielectric layer 165. Forming a trench (i.e., widen backside contact trench 173) to expose the backside surface of the first source/drain 130. Forming a sacrificial liner (i.e., sacrificial trench liner 180) on the sidewalls of the trench (i.e., widen backside contact trench 173). Growing a trench epi 185 from the backside surface of the first source/drain 130 and the sacrificial liner 180 acts a retaining wall for the trench epi growth. Removing the sacrificial liner 180 and forming a backside contact 190 that wraps around the trench epi 185 and is in contact with the backside surface of the first source/drain 130.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a nanosheet transistor that includes a first source/drain and a second source/drain;
a trench epi extending from a backside surface of the first source/drain; and
a backside contact that wraps around the trench epi and is in contact with a backside surface of the first source/drain.

2. The microelectronic structure of claim 1, wherein the backside surface of the first source/drain is curved from a gouging process.

3. The microelectronic structure of claim 2, wherein the trench epi includes a tip pointing towards the backside of the nanosheet transistor.

4. The microelectronic structure of claim 3, wherein the backside contact is in contact with the sidewalls of the trench epi.

5. The microelectronic structure of claim 4, wherein the backside contact is contact with the tip of the trench epi.

6. The microelectronic structure of claim 5, wherein the backside contact is in contact with the curved backside surface of the first source/drain.

7. The microelectronic structure of claim 1, wherein a first portion of a sidewall of the backside contact is in contact with a liner.

8. The microelectronic structure of claim 7, wherein a second portion of the sidewall of the backside contact is in contact with a shallow trench isolation layer.

9. The microelectronic structure of claim 8, wherein a third portion of the sidewall of the backside contact is in contact with a backside interlayer dielectric layer.

10. A microelectronic structure comprising:
a nanosheet transistor that includes a first source/drain and a second source/drain;
a bottom dielectric isolation layer located on a backside surface of the first source/drain;
a trench epi extending from a backside surface of the first source/drain, wherein the trench epi extends through the bottom dielectric layer; and
a backside contact that wraps around the trench epi and is in contact with a backside surface of the first source/drain.

11. The microelectronic structure of claim 10, wherein the backside contact is in contact with a plurality of sidewalls of the trench epi.

12. The microelectronic structure of claim 11, wherein the backside contact is contact with a top surface of the trench epi.

13. The microelectronic structure of claim 12, wherein the backside contact is in contact with a curved backside surface of the first source/drain.

14. The microelectronic structure of claim 13, wherein the backside contact is in contact with a backside surface of the bottom dielectric isolation layer.

15. The microelectronic structure of claim 10, wherein a first portion of a first sidewall of the backside contact is in contact with a liner.

16. The microelectronic structure of claim 15, wherein a second portion of the sidewall of the backside contact is in contact with a shallow trench isolation layer.

17. The microelectronic structure of claim 16, wherein a third portion of the first sidewall of the backside contact is in contact with a first backside interlayer dielectric layer.

18. The microelectronic structure of claim 17, wherein a first portion of a second sidewall of the backside contact is in contact with a second backside interlayer dielectric layer, and wherein a second portion of the second sidewall of the backside contact is in contact with the first backside interlayer dielectric layer.

19. The microelectronic structure of claim 18, wherein the first backside dielectric layer and the second backside dielectric layer are comprised of different dielectric materials.

20. A method comprising:
forming a nanosheet transistor that includes a first source/drain and a second source/drain;
flipping the nanosheet transistor over for backside processing;
forming a first backside interlayer dielectric layer and forming a second backside interlayer dielectric layer;
forming a trench to expose the backside surface of the first source/drain;
forming a sacrificial liner on the sidewalls of the trench;
growing a trench epi from the backside surface of the first source/drain, wherein the sacrificial liner acts a retaining wall for the trench epi growth;
removing the sacrificial liner; and
forming a backside contact that wraps around the trench epi and is in contact with the backside surface of the first source/drain.
